(19) United States
(12) Patent Application Publication
(10) Pub. No.: US 2022/0411550 A1
(43) Pub. Date: Dec. 29, 2022

(54) CROSSLINKABLE ELECTROACTIVE FLUOROPOLYMERS COMPRISING PHOTOACTIVE GROUPS

(71) Applicants: ARKEMA FRANCE, Colombes (FR); UNIVERSITE DE BORDEAUX, Bordeaux (FR); INSTITUT POLYTECHNIQUE DE BORDEAUX, Talence Cedex (FR); CENTRE NATIONAL DE LA RECHERCHE SCIENTIFIQUE, Paris (FR)

(72) Inventors: Fabrice DOMINGUES DOS SANTOS, Colombes Cedex (FR); Thibaut SOULESTIN, Pierre-Benite (FR); Georges HADZIIOANNOU, Leognan (FR); Eric CLOUTET, Begles (FR); Cyril BROCHON, Merignac (FR); Konstantinos KALLITSIS, Bordeaux (FR)

(73) Assignees: ARKEMA FRANCE, Colombes (FR); UNIVERSITE DE BORDEAUX, Bordeaux (FR); INSTITUT POLYTECHNIQUE DE BORDEAUX, Talence Cedex (FR); CENTRE NATIONAL DE LA RECHERCHE SCIENTIFIQUE, Paris (FR)

(21) Appl. No.: 17/414,721

(22) PCT Filed: Dec. 16, 2019
(86) PCT No.: PCT/FR2019/053073

§ 371 Date: Jun. 16, 2021

(30) Foreign Application Priority Data
Dec. 17, 2018 (FR) 1873059

(51) Int. Cl. C08F 214/22; C08F 214/24; C08F 220/18; G03F 7/004; G03F 7/033; G03F 7/30

(52) U.S. Cl. CPC C08F 214/22; C08F 214/24; C08F 220/18; G03F 7/0046; G03F 7/033; G03F 7/30

(57) ABSTRACT

A copolymer including fluorinated units of formula (I):

—CX₁X₂—CX₃X₄— (I)

in which each of the X₁, X₂, X₃ and X₄ is independently chosen from H, F and alkyl groups including from 1 to 3 carbon atoms which are optionally partially or totally fluorinated; and fluorinated units of formula (II):

—CX₅X₆—CX₇Z— (II)

in which each of the X₅, X₆ and X₇ is independently chosen from H, F and alkyl groups including from 1 to 3 carbon atoms which are optionally partially or totally fluorinated, and in which Z is a photoactive group of formula —Y—Ar—R, Y representing an oxygen atom or an NH group or a sulfur atom, Ar representing an aryl group, and R being a monodentate or bidentate group including from 1 to 30 carbon atoms. Also, a process for preparing this copolymer, a composition including this copolymer, and a film obtained from this copolymer.

### FIELD OF THE INVENTION

The present invention relates to crosslinkable electroactive fluoropolymers comprising photoactive groups, to a process for preparing same and to films manufactured therefrom.

### TECHNICAL BACKGROUND

Electroactive fluoropolymers or EAFPs are primarily derivatives of polyvinylidene fluoride (PVDF). In this regard, see the article Vinylidene fluoride- and trifluoroethylene-containing fluorinated electroactive copolymers. How does chemistry impact properties? by Soulestin et al., in Prog. Polym. Sci. 2017 (DOI: 10.1016/j.progpolymsci.2017.04.004). These polymers have particularly interesting dielectric and electromechanical properties. The fluorinated copolymers formed from vinylidene fluoride (VDF) and trifluoroethylene (TrFE) monomers are of particular interest on account of their piezoelectric, pyroelectric and ferroelectric properties. They notably allow the conversion of mechanical or thermal energy into electrical energy, or vice-versa.

Some of these fluorinated copolymers also include units obtained from another monomer bearing a chlorine, bromine or iodine substituent, and notably chlorotrifluoroethylene (CTFE) or chlorofluoroethylene (CFE). Such copolymers have a useful set of properties, namely a relaxor ferroelectric nature (characterized by a dielectric constant maximum, as a function of temperature, which is broad and dependent on the frequency of the electric field), a high dielectric constant, a high saturation polarization, and a semicrystalline morphology.

Electroactive fluoropolymers are shaped into films, generally by deposition using an ink formulation. During the production of electroactive devices, it may be necessary to make part or all of the film insoluble in accordance with a predefined pattern. The reason is that it is often necessary to deposit other layers over the polymer film, so as to manufacture the desired device. This deposition of other layers often involves the use of a solvent. If the electroactive fluoropolymer is not crosslinked, it may be degraded by this solvent during the deposition of the other layers.

Several methods have been proposed for crosslinking fluoropolymers. Among the crosslinking methods that are the most commonly used, mention may be made of heat treatment, irradiation with an electron beam, X-ray irradiation and UV irradiation.

The article by Tan et al. in J. Mat. Chem. A 2013 (pages 10353-10361) describes the crosslinking of a P(VDF-TrFE) copolymer by heat treatment in the presence of a peroxide compound.

The article by Shin et al. in Appl. Mater. Inter. 2011 (pages 582-589) describes the crosslinking of a P(VDF-TrFE) copolymer by heat treatment in the presence of another crosslinking agent, namely 2,4,4-trimethyl-1,6-hexanediamine.

However, crosslinking by heat treatment has the risk of destroying one or more layers of a multilayer electronic device because of the treatment of the device by heating. Furthermore, the heat treatment does not allow the production of films bearing defined units, since this crosslinking method makes selective crosslinking impossible.

The articles by Desheng et al. in Ferroelectrics 2001 (pages 21-26) and by Yang et al. in Polymer 2013 (pages 1709-1728) describe the crosslinking of fluoropolymers using irradiation with an electron beam.

The article by Mandal et al. in Appl. Surf. Sci. 2012 (pages 209-213) describes the crosslinking of fluoropolymers using X-ray irradiation.

Such irradiation is highly energetic and can therefore give rise to chemical side reactions affecting the structure of the polymer chains.

US 2007/0166838 describes a process for crosslinking fluoropolymers by UV irradiation in the presence of a bis-azide photoinitiator.

A similar technology is described in the articles by van Breemen et al. in Appl. Phys. Lett. 2011 (No. 183302) and by Chen et al. in Macromol. Rapid. Comm. 2011 (pages 94-99).

A similar technology is described in the articles by van Breemen et al. in Appl. Phys. Lett. 2011 (No. 183302) and by Chen et al. in Macromol. Rapid. Comm. 2011 (pages 94-99).

WO 2015/200872 describes a crosslinking composition comprising a polymer based on vinylidene fluoride, a non-nucleophilic photosensitive base and a crosslinking agent.

The article by Hou et al. in Polym. J. 2008 (pages 228-232) describes the crosslinking of acrylate polymers by UV irradiation in the presence of 4-methoxybenzophenone as photoinitiator and also of a coagent for activating the photoinitiator.

In all of these documents, the crosslinking requires the presence of a crosslinking agent in addition to the polymer. Adding this agent makes the preparation of the polymer film more complex and may give rise to deterioration of the electroactive properties. Reducing the number of components used in the formulation for preparing the polymer film is generally desirable.

The article by Kim et al. in Science 2012 (pages 1201-1205) describes the crosslinking of non-fluoro polymers comprising benzophenone molecules, by UV irradiation.

WO 2013/087500 describes a fluoropolymer manufactured by polymerizing VDF, TrFE, and a third monomer containing an azide group. This fluoropolymer may be subsequently crosslinked, preferably in the presence of a crosslinking agent.

WO 2013/087501 relates to a composition comprising a fluoropolymer comprising units derived from VDF and TrFE and a crosslinking agent comprising azide groups.

Document WO 2015/128337 describes a fluoropolymer prepared by polymerizing VDF, TrFE, and a third, (meth)acrylic monomer. This fluoropolymer may be subsequently crosslinked, preferably in the presence of a crosslinking agent.

WO 2010/021962 describes fluoropolymers comprising azide groups, which may be obtained either by reacting a fluoropolymer with an azide compound or by polymerizing monomers in the presence of an azide compound. The fluoropolymer examples given in the document are of copolymers based on VDF and HFP (hexafluoropropylene), or iodo-terminated polymers (PVDF-I and 1-iodoperfluorooctane) which react with sodium azide.

There is thus a real need to provide electroactive fluoropolymers which have the useful properties mentioned above (piezoelectric, pyroelectric and ferroelectric), which may subsequently be efficiently crosslinked while at the same time essentially conserving these useful properties after crosslinking.

### SUMMARY OF THE INVENTION

The invention relates first to a copolymer comprising:
fluorinated units of formula (I):

—CX₁X₂—CX₃X₄— (I)

in which each of the X₁, X₂, X₃ and X₄ is independently chosen from H, F and alkyl groups comprising from 1 to 3 carbon atoms which are optionally partially or totally fluorinated;
fluorinated units of formula (II):

—CX₅X₆—CX₇Z— (II)

in which each of the X₅, X₆ and X₇ is independently chosen from H, F and alkyl groups comprising from 1 to 3 carbon atoms which are optionally partially or totally fluorinated, and in which Z is a photoactive group of formula —Y—Ar—R, Y representing an O atom or an S atom or an NH group, Ar representing an aryl group, preferably a phenyl group, and R being a monodentate or bidentate group comprising from 1 to 30 carbon atoms.

In certain embodiments, the fluorinated units of formula (I) are derived from monomers chosen from vinylidene fluoride, trifluoroethylene and combinations thereof.

In certain embodiments, the fluorinated units of formula (I) comprise both units derived from vinylidene fluoride monomers and units derived from trifluoroethylene monomers, the proportion of units derived from trifluoroethylene monomers preferably being from 15 to 55 mol % relative to the sum of the units derived from vinylidene fluoride and trifluoroethylene monomers.

In certain embodiments, the molar proportion of fluorinated units of formula (I) relative to the total amount of units is less than 99% and preferably less than 95%.

In certain embodiments, the copolymer also comprises fluorinated units of formula (III):

—CX₅X₆—CX₇Z′— (III)

in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

In certain embodiments, the fluorinated units of formula (III) are derived from monomers chosen from chlorotrifluoroethylene and chlorofluoroethylene, notably 1-chloro-1-fluoroethylene.

In certain embodiments, the molar proportion of fluorinated units of formula (II) and of fluorinated units of formula (III) relative to the total amount of units is at least 1% and preferably at least 5%.

In certain embodiments, the molar proportion of fluorinated units of formula (II) relative to the sum of the fluorinated units of formula (II) and of formula (III) is from 5% to 90%, preferably from 10% to 75% and more preferably from 15% to 40%.

In certain embodiments, the group Ar is substituted with the group R in the ortho position relative to Y, and/or in the meta position relative to Y, and/or in the para position relative to Y.

In certain embodiments, the group R comprises a carbonyl function and is preferably chosen from an acetyl group, a substituted or unsubstituted benzoyl group, a substituted or unsubstituted phenylacetyl group, a phthaloyl group, and a phosphine oxide acyl group; the phosphine being substituted with one or more groups chosen from a methyl group, an ethyl group and a phenyl group.

In certain embodiments, the group Ar is a phenyl substituted in the meta position and the group R is an unsubstituted benzoyl group, or the group Ar is a phenyl substituted in the para position and the group R is an unsubstituted benzoyl group, or the group Ar is a phenyl substituted in the para position and the group R is a benzoyl group substituted in the para position with a hydroxyl group, or the group Ar is a phenyl substituted in the meta position and the group R is an acetyl group, or the group Ar is a phenyl substituted in the para position and the group R is an acetyl group, or the group Ar is a phenyl substituted in the ortho position and the group R is a phenylacetyl group substituted α to the carbonyl group with a hydroxyl group, or the group Ar is a phenyl substituted in the meta position and the group R is a phenylacetyl group substituted α to the carbonyl group with a hydroxyl group, or the group Ar is a phenyl substituted in the ortho position and the group R is a phosphine oxide acyl group, or the group Ar is a phenyl substituted in the meta position and the group R is a phosphine oxide acyl group, or the group Ar is a phenyl substituted in the para position and the group R is a phosphine oxide acyl group, or the group Ar is a phenyl substituted in the ortho and meta positions and the group R is a phthaloyl group.

The invention also relates to a process for preparing a copolymer as described above, comprising:
the provision of a starting copolymer comprising fluorinated units of formula (I):

—CX₁X₂—CX₃X₄— (I)

in which each of the X₁, X₂, X₃ and X₄ is independently chosen from H, F and alkyl groups comprising from 1 to 3 carbon atoms which are optionally partially or totally fluorinated;

and fluorinated units of formula (III):

—CX₅X₆—CX₇Z′— (III)

in which each of the X₅, X₆ and X₇ is independently chosen from H, F and alkyl groups comprising from 1 to 3 carbon atoms which are optionally partially or totally fluorinated, and in which Z′ is chosen from Cl, Br and I;
and placing of the starting copolymer in contact with a photoactive molecule of formula HY—Ar—R, Y representing an O atom or an S atom, or an NH group, Ar representing an aryl group, preferably a phenyl group, and R being a monodentate or bidentate group comprising from 1 to 30 carbon atoms.

In certain embodiments, the placing in contact is performed in a solvent preferably chosen from: dimethyl sulfoxide; dimethylformamide; dimethylacetamide; ketones, notably acetone, methyl ethyl ketone, methyl isobutyl ketone and cyclopentanone; furans, notably tetrahydrofuran; esters, notably methyl acetate, ethyl acetate, propyl acetate, butyl acetate and propylene glycol methyl ether acetate; carbonates, notably dimethyl carbonate; and phosphates, notably triethyl phosphate.

In certain embodiments, the process also comprises a step of reacting the photoactive molecule with a base, before placing the starting copolymer in contact with the photoactive molecule, the base preferably being potassium carbonate.

In certain embodiments, the placing of the starting copolymer in contact with the photoactive molecule is performed at a temperature of from 20 to 120° C. and preferably from 30 to 90° C.

The invention also relates to a composition comprising the copolymer as described above, in which the composition is a solution or dispersion of the copolymer in a liquid vehicle.

In certain embodiments, the composition also comprises a second copolymer comprising:
fluorinated units of formula (I):

—CX₁X₂—CX₃X₄— (I)

in which each of the X₁, X₂, X₃ and X₄ is independently chosen from H, F and alkyl groups comprising from 1 to 3 carbon atoms which are optionally partially or totally fluorinated;
fluorinated units of formula (III):

—CX₅X₆—CX₇Z′— (III)

in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

In certain embodiments, the fluorinated units of formula (I) of the second copolymer are chosen from units derived from vinylidene fluoride and/or trifluoroethylene.

In certain embodiments, the second copolymer comprises both fluorinated units of formula (I) derived from vinylidene fluoride monomers and fluorinated units of formula (I) derived from trifluoroethylene monomers, the proportion of units derived from trifluoroethylene monomers being preferably from 15 to 55 mol % relative to the sum of the units derived from vinylidene fluoride and trifluoroethylene monomers.

In certain embodiments, the fluorinated units of formula (III) are chosen from units derived from chlorotrifluoroethylene and chlorofluoroethylene, notably 1-chloro-1-fluoroethylene.

In certain embodiments, the composition comprises from 5% to 95% by weight of copolymer as described above and from 5% to 95% by weight of the second copolymer; preferably from 30% to 70% by weight of copolymer as described above and from 30% to 70% by weight of second copolymer; the contents being expressed relative to the sum of the copolymer as described above and of the second copolymer.

In certain embodiments, the composition also comprises at least one (meth)acrylic monomer which is bifunctional or polyfunctional in terms of reactive double bonds.

In certain embodiments, said (meth)acrylic monomer which is bifunctional or polyfunctional in terms of reactive double bonds is a monomer or an oligomer containing at least two reactive double bonds of (meth)acrylic type or a bifunctional or polyfunctional (meth)acrylic monomer or oligomer chosen from diols, triols or polyols, polyesters, ethers, polyethers, polyurethane, epoxies, cyanurates or isocyanurates.

In certain embodiments, said (meth)acrylic monomer is chosen from the list of the following compounds: dodecane dimethacrylate, 1,3-butylene glycol di(meth)acrylate, butanediol di(meth)acrylate, 1,6-hexanediol di(meth)acrylate, alkoxylated hexanediol di(meth)acrylate, alkoxylated neopentyl glycol di(meth)acrylate, dodecyl di(meth)acrylate, cyclohexanedimethanol di(meth)acrylate, diethylene glycol di(meth)acrylate, dipropylene glycol di(meth)acrylate, linear alkane di(meth)acrylate, ethoxylated bisphenol A di(meth)acrylate, ethylene glycol di(meth)acrylate, neopentyl glycol di(meth)acrylate, tricyclodecanedimethanol diacrylate, triethylene glycol di(meth)acrylate, tetraethylene glycol di(meth)acrylate, tripropylene glycol di(meth)acrylate, ditrimethylolpropane tetra(meth)acrylate, ethoxylated pentaerythritol tetra(meth)acrylate, dipentaerythritol penta(meth)acrylate, penta(meth)acrylate ester, pentaerythritol tetra(meth)acrylate, ethoxylated trimethylolpropane tri(meth)acrylate, alkoxylated trimethylolpropane tri(meth)acrylate, trimethylolpropane tri(meth)acrylate, pentaerythritol tri(meth)acrylate, propoxylated trimethylolpropane tri(meth)acrylate, trimethylolpropane trimethacrylate, dodecanediol di(meth)acrylate, dodecane di(meth)acrylate, dipentaerythritol penta/hexa(meth)acrylate, pentaerythritol tetra(meth)acrylate, ditrimethylolpropane tetra(meth)acrylate, propoxylated glyceryl tri(meth)acrylate, tris(2-hydroxyethyl) isocyanurate tri(meth)acrylate, polyester (meth)acrylates, polyether (meth)acrylates, polyethylene glycol (meth)acrylates, polypropylene glycol (meth)acrylates, polyurethane (meth)acrylates, epoxy (meth)acrylates, and combinations thereof.

The invention also relates to a process for manufacturing a film, comprising:
depositing a copolymer as described above or a composition as described above onto a substrate;
crosslinking the copolymer or the composition.

In certain embodiments, the crosslinking is performed according to a predefined pattern, the process subsequently comprising the removal of portions of copolymer or composition not crosslinked, by placing them in contact with a solvent.

The invention also relates to a film obtained by the process described above.

The invention also relates to an electronic device comprising a film as described above, the electronic device being preferably chosen from field-effect transistors, memory devices, condensers, sensors, actuators, electromechanical microsystems and haptic devices.

The present invention makes it possible to overcome the drawbacks of the prior art. It more particularly provides electroactive fluoropolymers which have the useful properties mentioned above (piezoelectric, pyroelectric and ferroelectric), and, for example, a high dielectric constant, which may subsequently be efficiently crosslinked while at the same time essentially conserving these useful properties after crosslinking. After crosslinking, the invention makes it possible to obtain insoluble polymer films which have predefined patterns and which advantageously have one or more (and preferably all) of the following properties: a semicrystalline morphology, a high dielectric constant, a high saturation polarization, and a Curie transition. These predefined patterns may be obtained, for example, by means of UV irradiation which allows the crosslinking of a portion of the polymer film, followed by a developing step so as to remove the non-crosslinked portions.

Furthermore, the invention makes it possible to achieve crosslinking without recourse to excessive energy irradiation, thus avoiding the degradation of other layers in multilayer electric devices, and without necessarily adding any crosslinking agent.

However, in certain variants of the invention, the presence of a crosslinking coagent may be advantageous given that the photoactive groups present in the copolymer can make it possible to initiate a radical polymerization reaction.

The invention is based on the use of copolymers comprising pattern bearing photoactive groups. These copolymers may be prepared from copolymers bearing leaving groups (Cl, Br or I), which are totally or partly replaced with photoactive groups, which allow the crosslinking. This replacement may be performed simply by reacting the starting copolymer with a photoactive molecule. Preferably, some of the leaving groups are conserved, so that the copolymer conserves the advantageous properties associated with the presence of these leaving groups.

One advantage of the invention is that it makes it possible to obtain crosslinkable polymers from ranges of existing polymers whose synthesis is fully controlled, and hence does not require the development of new polymerization processes.

Two embodiments may in particular be envisaged for implementing the invention:
it is possible to use a single fluoropolymer, to treat it with a photoactive molecule so as to partially replace the leaving groups of the fluoropolymer with photoactive groups, and then to crosslink this fluoropolymer;
it is possible to use a blend of fluoropolymers, only one of which has had leaving groups replaced with photoactive groups, and then to crosslink this blend of fluoropolymers.

### BRIEF DESCRIPTION OF THE FIGURES

FIG. 1 is a graph showing the infrared absorption spectra of the polymer according to the invention before (dashed line) and after (continuous line) modification with the photoactive groups of formula —O—Ar—R. The wavenumber in cm⁻¹ is given on the x-axis.

FIG. 2 is a graph showing the ¹H NMR spectra of the polymer according to the invention before (A) and after (B) modification with the photoactive groups of formula —O—Ar—R. The chemical shift in ppm is given on the x-axis.

FIG. 3 is a photograph obtained by light microscopy of a polymer film according to the invention (in accordance with example 2). The scale bar corresponds to 500 μm.

FIG. 4 is a curve of relative dielectric permittivity at 1 kHz at various temperatures of the polymer film according to example 2. The y-axis corresponds to the relative dielectric permittivity (unitless) and the x-axis corresponds to the temperature in degrees Celsius.

### DETAILED DESCRIPTION

The invention is now described in greater detail and in a non-limiting manner in the description that follows.

The invention is based on the use of fluoropolymers, referred to hereinbelow as FP polymers. These FP polymers may be used as starting polymers and modified for grafting with photoactive groups; the fluoropolymers thus modified are referred to hereinbelow as MFP polymers.

### FP Polymer

According to the invention, an FP polymer comprises: -
fluorinated units of formula (I):

—CX₁X₂—CX₃X₄— (I)

in which each of the X₁, X₂, X₃ and X₄ is independently chosen from H, F and alkyl groups comprising from 1 to 3 carbon atoms which are optionally partially or totally fluorinated;
fluorinated units of formula (III):

—CX₅X₆—CX₇Z′— (III)

in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

The fluorinated units of formula (I) are derived from monomers of formula CX₁X₂═CX₃X₄ and the fluorinated units of formula (III) are derived from monomers of formula CX₅X₆═CX₇Z′.

The fluorinated units of formula (I) include at least one fluorine atom.

The fluorinated units of formula (I) preferably include not more than 5 carbon atoms, more preferably not more than 4 carbon atoms, more preferably not more than 3 carbon atoms, and more preferably it includes 2 carbon atoms.

In certain embodiments, each group X₁, X₂, X₃ and X₄ independently represents an H or F atom or a methyl group optionally including one or more substituents chosen from H and F.

In certain embodiments, each group X₁, X₂, X₃ and X₄ independently represents an H or F atom.

Particularly preferably, the fluorinated units of formula (I) are derived from a fluorinated monomer chosen from vinyl fluoride (VF), vinylidene fluoride (VDF), trifluoroethylene (TrFE), tetrafluoroethylene (TFE), hexafluoropropylene (HFP), trifluoropropenes and notably 3,3,3-trifluoropropene, tetrafluoropropenes and notably 2,3,3,3-tetrafluoropropene or 1,3,3,3-tetrafluoropropene, hexafluoroisobutylene, perfluorobutylethylene, pentafluoropropenes and notably 1,1,3,3,3-pentafluoropropene or 1,2,3,3,3-pentafluoropropene, perfluoroalkyl vinyl ethers and notably those of general formula Rf—O—CF—CF₂, Rf being an alkyl group, preferably of C1 to C4 (preferred examples being perfluoropropyl vinyl ether or PPVE and perfluoromethyl vinyl ether or PMVE).

The most preferred fluoro monomers comprising fluorinated units of formula (I) are vinylidene fluoride (VDF) and trifluoroethylene (TrFE).

The fluorinated units of formula (III) include at least one fluorine atom.

The fluorinated units of formula (III) preferably include not more than 5 carbon atoms, more preferably not more than 4 carbon atoms, more preferably not more than 3 carbon atoms, and more preferably it includes 2 carbon atoms.

In certain embodiments, each group X₅, X₆ and X₇ independently represents an H or F atom or a C1-C3 alkyl group optionally including one or more fluorine substituents; preferably, an H or F atom or a C1-C2 alkyl group optionally including one or more fluorine substituents; and more preferably an H or F atom or a methyl group optionally including one or more fluorine substituents, and Z′ may be chosen from Cl, I and Br.

In certain embodiments, each group X₅, X₆ and X₇ independently represents an H or F atom or a methyl group optionally including one or more substituents chosen from H and F, and Z′ may be chosen from Cl, I and Br.

In certain embodiments, each group X₅, X₆ and X₇ independently represents an H or F atom, and Z′ may be chosen from Cl, I and Br.

Particularly preferably, the fluorinated units of formula (III) are derived from a fluoro monomer chosen from bromotrifluoroethylene, chlorofluoroethylene, chlorotrifluoroethylene and chlorotrifluoropropene. Chlorofluoroethylene may denote either 1-chloro-1-fluoroethylene or 1-chloro-2-fluoroethylene. The 1-chloro-1-fluoroethylene isomer is preferred. Chlorotrifluoropropene is preferably 1-chloro-3,3,3-trifluoropropene or 2-chloro-3,3,3-trifluoropropene.

The most preferred fluoro monomers comprising fluorinated units of formula (III) are chlorotrifluoroethylene (CTFE) and chlorofluoroethylene, notably 1-chloro-1-fluoroethylene (CFE).

In certain embodiments, the FP polymer consists of fluorinated units of formula (I) and fluorinated units of formula (III).

In certain preferred variants, the FP polymer is a P(VDF-CTFE) copolymer.

In certain preferred variants, the FP polymer is a P(TrFE-CTFE) copolymer.

In yet other variations, fluorinated units of formula (I) derived from several different fluoro monomers may be present in the FP polymer.

The FP polymer preferably comprises units simultaneously derived from VDF, TrFE and CTFE.

In certain preferred variations, the FP polymer is a P(VDF-TrFE-CTFE) terpolymer.

The FP polymer preferably comprises units simultaneously derived from VDF, TrFE and CTFE.

In yet other variations, fluorinated units of formula (III) derived from several different fluoro monomers may be present in the FP polymer.

In yet other variations, units derived from one or more additional monomers, further to those mentioned above, may be present in the FP polymer.

The proportion of units derived from TrFE is preferably from 5 to 95 mol %, relative to the sum of the units derived from VDF and TrFE, and notably from 5 to 10 mol %; or from 10 to 15 mol %; or from 15 to 20 mol %; or from 20 to 25 mol %; or from 25 to 30 mol %; or from 30 to 35 mol %; or from 35 to 40 mol %; or from 40 to 45 mol %; or from 45 to 50 mol %; or from 50 to 55 mol %; or from 55 to 60 mol %; or from 60 to 65 mol %; or from 65 to 70 mol %; or from 70 to 75 mol %; or from 75 to 80 mol %; or from 80 to 85 mol %; or from 85 to 90 mol %; or from 90 to 95 mol %. A range from 15 to 55 mol % is particularly preferred.

The proportion of fluorinated units of formula (I) in the FP polymer (relative to the total amount of units) may be less than 99 mol %, and preferably less than 95 mol %.

The proportion of units of formula (I) in the FP polymer (relative to the total amount of units) may range, for example, from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %; or from 50 to 60 mol %; or from 60 to 70 mol %; or from 70 to 80 mol %; or from 80 to 90 mol %; or from 90 to 95 mol %; or from 95 to 99 mol %.

The proportion of fluorinated units of formula (III) in the FP polymer (relative to the total amount of units) may be at least 1 mol %, and preferably at least 5 mol %.

The proportion of fluorinated units of formula (III) in the FP polymer (relative to the total amount of units) may range, for example, from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %; or from 50 to 60 mol %; or from 60 to 70 mol %; or from 70 to 80 mol %; or from 80 to 90 mol %; or from 90 to 95 mol %; or from 95 to 99 mol %; or from 99 to 99.5 mol %.

The molar composition of the units in the FP polymers may be determined by various means such as infrared spectroscopy or RAMAN spectroscopy. Conventional methods of elemental analysis of carbon, fluorine and chlorine or bromine or iodine elements, such as X-ray fluorescence spectroscopy, make it possible to calculate unambiguously the mass composition of the polymers, from which the molar composition is deduced.

Use may also be made of multinuclear, notably proton (¹H) and fluorine (¹⁹F), NMR techniques, by analysis of a solution of the polymer in a suitable deuterated solvent. The NMR spectrum is recorded on an FT-NMR spectrometer equipped with a multinuclear probe. The specific signals given by the various monomers in the spectra produced according to one or other nucleus are then identified. Thus, for example, the unit derived from TrFE gives, in proton NMR, a specific signal characteristic of the CFH group (at about 5 ppm). The same is true for the CH₂ groups of VDF (broad unresolved peak centred at 3 ppm). The relative integration of the two signals gives the relative abundance of the two monomers, i.e. the VDF/TrFE mole ratio.

Similarly, the —CFH-group of TrFE, for example, gives characteristic and well-isolated signals in fluorine NMR. The combination of the relative integrations of the various signals obtained in proton NMR and in fluorine NMR results in a system of equations whose solution provides the molar concentrations of the units derived from the various monomers.

Finally, it is possible to combine elemental analysis, for example for the heteroatoms, such as chlorine or bromine or iodine, and NMR analysis. Thus, the content of units derived from CTFE, for example, can be determined by measuring the chlorine content by elemental analysis.

A person skilled in the art thus has available a range of methods or a combination of methods allowing him to determine, without ambiguity and with the necessary accuracy, the composition of the FP polymers.

The FP polymer is preferably random and linear.

It is advantageously thermoplastic and not, or not very, elastomeric (as opposed to a fluoroelastomer).

The FP polymer may be homogeneous or heterogeneous. A homogeneous polymer has a uniform chain structure, the statistical distribution of the units derived from the various monomers varying very little between the chains. In a heterogeneous polymer, the chains have a distribution of units derived from the various monomers of multimodal or spread-out type. A heterogeneous polymer therefore comprises chains richer in a given unit and chains poorer in this unit. An example of a heterogeneous polymer appears in WO 2007/080338.

The FP polymer is an electroactive polymer.

In particular, preferably, it has a dielectric permittivity maximum of 0 to 150° C., preferably of 10 to 140° C. In the case of ferroelectric polymers, this maximum is called the “Curie temperature” and corresponds to the transition from a ferroelectric phase to a paraelectric phase. This temperature maximum, or transition temperature, may be measured by differential scanning calorimetry or by dielectric spectroscopy.

The polymer preferably has a melting point of 90 to 180° C., more particularly of 100 to 170° C. The melting point may be measured by differential scanning calorimetry according to the standard ASTM D3418.

### Manufacture of an FP Polymer

Although the FP polymer can be produced using any known process, such as emulsion polymerization, suspension polymerization and solution polymerization, it is preferable to use the process described in WO 2010/116105. This process makes it possible to obtain polymers of high molecular weight and of suitable structuring.

In short, the preferred process comprises the following steps:
loading an initial mixture containing only the fluoro monomer(s) giving the units of formula (I) (without the fluoro monomer(s) giving the units of formula (III)) into a stirred autoclave containing water;
heating the autoclave to a predetermined temperature, close to the polymerization temperature;
injecting a radical polymerization initiator mixed with water into the autoclave, in order to achieve a pressure in the autoclave which is preferably at least 80 bar, so as to form a suspension of the fluorinated monomers of formula (I) in water;
injecting a second mixture of fluorinated monomer(s) giving the units of formula (I) and of fluorinated monomer(s) giving the units of formula (III) (and optionally of additional monomers, if any) into the autoclave;
as soon as the polymerization reaction begins, continuously injecting said second mixture into the autoclave reactor, in order to maintain the pressure at an essentially constant level, preferably of at least 80 bar.

The radical polymerization initiator may notably be an organic peroxide of peroxydicarbonate type. It is generally used in an amount of 0.1 to 10 g per kilogram of total monomer charge. The amount used is preferably from 0.5 to 5 g/kg.

The initial mixture advantageously comprises only the fluorinated monomer(s) giving the units of formula (I) in a proportion equal to that of the desired final polymer.

The second mixture advantageously has a composition which is adjusted such that the total composition of monomers introduced into the autoclave, including the initial mixture and the second mixture, is equal or approximately equal to the composition of the desired final polymer.

The weight ratio of the second mixture to the initial mixture is preferably from 0.5 to 2, more preferably from 0.8 to 1.6.

The implementation of this process with an initial mixture and a second mixture makes the process independent of the reaction initiation phase, which is often unpredictable. The polymers thus obtained are in the form of a powder, without crust or skin.

The pressure in the autoclave reactor is preferably from 80 to 110 bar, and the temperature is maintained at a level preferably from 40° C. to 60° C.

The second mixture can be injected continuously into the autoclave. It can be compressed before being injected into the autoclave, for example using a compressor or two successive compressors, generally to a pressure greater than the pressure in the autoclave.

After synthesis, the polymer can be washed and dried.

The weight-average molar mass Mw of the polymer is preferably at least 100 000 g·mol⁻¹, preferably at least 200 000 g·mol⁻¹ and more preferably at least 300 000 g·mol⁻¹ or at least 400 000 g·mol⁻¹. It can be adjusted by modifying certain process parameters, such as the temperature in the reactor, or by adding a transfer agent.

The molecular weight distribution can be estimated by SEC (size exclusion chromatography) in dimethylformamide (DMF) as eluent, with a set of three columns of increasing porosity. The stationary phase is a styrene-DVB gel. The detection method is based on measurement of the refractive index, and calibration is performed with polystyrene standards. The sample is dissolved at 0.5 g/l in DMF and filtered through a 0.45 μm nylon filter.

### MFP Polymer

The MFP polymer may be manufactured from an FP polymer by reaction with a photoactive molecule of formula HY—Ar—R according to the Williamson reaction, so as to incorporate into the polymer chain photoactive groups of formula —Y—Ar—R, in which Y represents an O atom or an S atom, or an NH group, Ar represents an aryl group, preferably a phenyl group, and R is a monodentate or bidentate group comprising from 1 to 30 carbon atoms.

The term “monodentate group” means a group which bonds to the group Ar via only one atom of this group R.

The term “bidentate group” means a group which binds to the group Ar via two different atoms of this group R, preferably on two different positions of the group Ar.

In certain embodiments, the group Ar may be substituted with the group R in the ortho position relative to Y, and/or in the meta position relative to Y, and/or in the para position relative to Y.

The group R may notably comprise from 2 to 20 carbon atoms, or from 3 to 15 carbon atoms, or from 4 to 10 carbon atoms, and more preferably from 6 to 8 carbon atoms.

The group R may comprise an alkyl or aryl or arylalkyl or alkenylaryl chain, which may be substituted or unsubstituted. It may comprise one or more heteroatoms chosen from: O, N, S, P, F, Cl, Br, I.

The group R may preferably comprise a carbonyl function and may preferably be chosen from an acetyl group, a substituted or unsubstituted benzoyl group, a substituted or unsubstituted phenylacetyl group, a phthaloyl group, and a phosphine oxide acyl group; the phosphine being optionally substituted with one or more groups chosen from a methyl group, an ethyl group and a phenyl group.

In certain embodiments, the only substituent on the group Ar is the group R. In other embodiments, it may also comprise one (or more) additional substituents, comprising from 1 to 30 carbon atoms. The additional substituent may comprise one or more heteroatoms chosen from: O, N, S, P, F, Cl, Br, I. In addition, the additional substituent may be, for example, an aliphatic carbon-based chain. Alternatively, the additional substituent may be a substituted or unsubstituted aryl group, preferably a phenyl group, or an aromatic or non-aromatic heterocycle.

In certain embodiments, the group Ar is a phenyl substituted in the meta position and the group R is an unsubstituted benzoyl group, or the group Ar is a phenyl substituted in the para position and the group R is an unsubstituted benzoyl group, or the group Ar is a phenyl substituted in the para position and the group R is a benzoyl group substituted in the para position with a hydroxyl group, or the group Ar is a phenyl substituted in the meta position and the group R is an acetyl group, or the group Ar is a phenyl substituted in the para position and the group R is an acetyl group, or the group Ar is a phenyl substituted in the ortho position and the group R is a phenylacetyl group substituted α to the carbonyl group with a hydroxyl group, or the group Ar is a phenyl substituted in the meta position and the group R is a phenylacetyl group substituted α to the carbonyl group with a hydroxyl group, or the group Ar is a phenyl substituted in the ortho position and the group R is a phosphine oxide acyl group, or the group Ar is a phenyl substituted in the meta position and the group R is a phosphine oxide acyl group, or the group Ar is a phenyl substituted in the para position and the group R is a phosphine oxide acyl group, or the group Ar is a phenyl substituted in the ortho and meta positions and the group R is a phthaloyl group.

Preferably, Y is an oxygen atom.

Thus, the photoactive molecules may be chosen, for example, from 3-hydroxybenzophenone, 4-hydroxybenzophenone, 1-hydroxyanthraquinone, 2-hydroxyanthraquinone, 3-hydroxyacetophenone, 4-hydroxyacetophenone, 4,4-dihydroxybenzophenone, 2-hydroxybenzoin, 4-hydroxybenzoin, ethyl-(4-hydroxy-2,6-dimethylbenzoyl) phenylphosphinate and (4-hydroxy-4,6-trimethylbenzoyl)(2,4,6-trimethylbenzoyl)phenylphosphine oxide.

The photoactive molecules may also be chosen from: 2-hydroxy-2-methyl-1-phenylpropan-1-one, the phenyl group also being substituted with a hydroxyl group in the ortho, meta or para position relative to the carbonyl group; 2,4,6-trimethylbenzoyldiphenylphosphine oxide, the phenyl group also being substituted with a hydroxyl group in the meta position relative to the carbonyl group; 2,4,6-trimethylbenzoylethylphenylphosphinate, the phenyl group also being substituted with a hydroxyl group in the meta position relative to the carbonyl group; 1-hydroxycyclohexyl phenyl ketone, the phenyl group also being substituted with a hydroxyl group in the ortho, meta or para position relative to the carbonyl group; bis(2,6-dimethoxybenzoyl)-2,4,4-trimethylpentylphosphine oxide, the phenyl group also being substituted with a hydroxyl group in the meta or para position relative to the carbonyl group; 1-[4-(2-hydroxyethoxy)phenyl]-2-hydroxy-2-methyl-1-propan-1-one, the phenyl group also being substituted with a hydroxyl group in the ortho or meta position relative to the carbonyl group; 2,2-dimethoxy-1,2-diphenylethan-1-one, the phenyl group also being substituted with a hydroxyl group in the ortho, meta or para position relative to the carbonyl group; 2-methyl-1[4-(methylthio)phenyl]-2-morpholinopropan-1-one, the phenyl group also being substituted with a hydroxyl group in the ortho or meta position relative to the carbonyl group; and 2,4-diethylthioxanthone, the thioxanthone group also being substituted with a hydroxyl group.

Alternatively, Y may be an NH group.

Thus, the photoactive molecules may also be chosen from: 2-hydroxy-2-methyl-1-phenylpropan-1-one, the phenyl group also being substituted with an amine group in the ortho, meta or para position relative to the carbonyl group; 2,4,6-trimethylbenzoyldiphenylphosphine oxide, the phenyl group also being substituted with an amine group in the meta position relative to the carbonyl group; 2,4,6-trimethylbenzoylethylphenylphosphinate, the phenyl group also being substituted with an amine group in the meta position relative to the carbonyl group; 1-hydroxycyclohexyl phenyl ketone, the phenyl group also being substituted with an amine group in the ortho, meta or para position relative to the carbonyl group; bis(2,6-dimethoxybenzoyl)-2,4,4-trimethylpentylphosphine oxide, the phenyl group also being substituted with an amine group in the meta or para position relative to the carbonyl group; 1-[4-(2-hydroxyethoxy)phenyl]-2-hydroxy-2-methyl-1-propan-1-one, the phenyl group also being substituted with an amine group in the ortho or meta position relative to the carbonyl group; 2,2-dimethoxy-1,2-diphenylethan-1-one, the phenyl group also being substituted with an amine group in the ortho, meta or para position relative to the carbonyl group; 2-methyl-1[4-(methylthio)phenyl]-2-morpholinopropan-1-one, the phenyl group also being substituted with an amine group in the ortho or meta position relative to the carbonyl group; and 2,4-diethylthioxanthone, the thioxanthone group also being substituted with an amine group.

Alternatively, Y may be a sulfur atom.

Thus, the photoactive molecules may also be chosen from: 2-hydroxy-2-methyl-1-phenylpropan-1-one, the phenyl group also being substituted with a thiol group in the ortho, meta or para position relative to the carbonyl group; 2,4,6-trimethylbenzoyldiphenylphosphine oxide, the phenyl group also being substituted with a thiol group in the meta position relative to the carbonyl group; 2,4,6-trimethylbenzoylethylphenylphosphinate, the phenyl group also being substituted with a thiol group in the meta position relative to the carbonyl group; 1-hydroxycyclohexyl phenyl ketone, the phenyl group also being substituted with a thiol group in the ortho, meta or para position relative to the carbonyl group; bis(2,6-dimethoxybenzoyl)-2,4,4-trimethylpentylphosphine oxide, the phenyl group also being substituted with a thiol group in the meta or para position relative to the carbonyl group; 1[4-(2-hydroxyethoxy)phenyl]-2-hydroxy-2-methyl-1-propan-1-one, the phenyl group also being substituted with a thiol group in the ortho or meta position relative to the carbonyl group; 2,2-dimethoxy-1,2-diphenylethan-1-one, the phenyl group also being substituted with a thiol group in the ortho, meta or para position relative to the carbonyl group; 2-methyl-1[4-(methylthio)phenyl]-2-morpholinopropan-1-one, the phenyl group also being substituted with a thiol group in the ortho or meta position relative to the carbonyl group; and 2,4-diethylthioxanthone, the thioxanthone group also being substituted with a thiol group.

The FP polymer may be converted into an MFP polymer by combining the FP polymer and the photoactive molecule in a solvent in which the FP polymer is dissolved.

The solvent used may notably be dimethylformamide; dimethylacetamide; dimethyl sulfoxide; ketones, notably acetone, methyl ethyl ketone (or butan-2-one), methyl isobutyl ketone and cyclopentanone; furans, notably tetrahydrofuran; esters, notably methyl acetate, ethyl acetate, propyl acetate, butyl acetate and propylene glycol methyl ether acetate; carbonates, notably dimethyl carbonate; and phosphates, notably triethyl phosphate. Mixtures of these compounds may also be used.

The photoactive molecule may be reacted with a base before being placed in contact with the FP polymer in the solvent, so as to deprotonate the photoactive molecule and to form a photoactive anion of formula —Y—Ar—R, in which Y, Ar and R are as defined above.

The base used for deprotonating the photoactive molecule may have a pKa of from 9 to 12.5 and preferably from 10 to 12.

The base used for deprotonating the photoactive molecule is preferably chosen from potassium carbonate, calcium carbonate and sodium carbonate, and is preferably potassium carbonate.

The base may be used in a molar amount of from 1 to 1.25 equivalents, or from 1.25 to 1.5 equivalents, or from 1.5 to 2.0 equivalents, or from 2.0 to 3.0 equivalents, or from 3.0 to 4.0 equivalents, or from 4.0 to 5.0 equivalents, or from 5.0 to 6.0 equivalents, or from 6.0 to 7.0 equivalents, or from 7.0 to 8.0 equivalents relative to the photoactive molecule.

The reaction of the photoactive molecule with the base may be performed in a solvent, as mentioned above.

The solvent used for the reaction of the photoactive molecule with the base may be the same as or different from the solvent used for placing the FP polymer in contact with the photoactive molecule. Preferably, the solvent used for the reaction of the photoactive molecule with the base is the same as that used for placing the FP polymer in contact with the photoactive molecule.

The reaction of the photoactive molecule with the base may be performed at a temperature of from 20 to 80° C., more preferably from 30 to 70° C.

The duration of the reaction of the photoactive molecule with the base may be, for example, from 5 minutes to 5 hours, preferably from 15 minutes to 2 hours, more preferably from 30 minutes to 1 hour.

In certain embodiments, the step of reacting the photoactive molecule with the base may be followed by a step of removing the excess base.

The concentration of polymer PF introduced into the reaction mixture may be, for example, from 1 to 200 g/l, preferably from 5 to 100 g/l, and more preferably from 10 to 50 g/l.

The amount of photoactive molecules introduced into the reaction mixture may be adjusted according to the desired degree of replacement of the leaving groups with the photoactive groups. Thus, this amount may be from 0.1 to 0.2 molar equivalent (of photoactive groups introduced into the reaction medium, relative to the leaving groups Cl, Br or I present in the FP polymer); or from 0.2 to 0.3 molar equivalent; or from 0.3 to 0.4 molar equivalent; or from 0.4 to 0.5 molar equivalent; or from 0.5 to 0.6 molar equivalent; or from 0.6 to 0.7 molar equivalent; or from 0.7 to 0.8 molar equivalent; or from 0.8 to 0.9 molar equivalent; or from 0.9 to 1.0 molar equivalent; or from 1.0 to 1.5 molar equivalents; or from 1.5 to 2 molar equivalents; or from 2 to 5 molar equivalents; or from 5 to 10 molar equivalents; or from 10 to 50 molar equivalents.

The reaction of the FP polymer with the photoactive molecule is preferably performed with stirring.

The reaction of the FP polymer with the photoactive molecule is preferably performed at a temperature of from 20 to 120° C., more preferably from 30 to 90° C. and more particularly from 40 to 70° C.

The duration of the reaction of the FP polymer with the photoactive molecule may be, for example, from 15 minutes to 96 hours, preferably from 1 hour to 84 hours, more preferably from 2 hours to 72 hours.

When the desired reaction time has been reached, the MFP polymer may be precipitated from a non-solvent, for example deionized water. It may subsequently be filtered and dried.

The composition of the MFP polymer may be characterized by elemental analysis and by NMR, as described above, and also by infrared spectrometry. In particular, valency vibration bands characteristic of the aromatic and carbonyl functions are observed between 1500 and 1900 cm⁻¹.

In certain embodiments, all of the leaving groups Cl, Br or I of the starting FP polymer are replaced with photoactive groups in the MFP polymer.

In other (preferred) embodiments, the leaving groups Cl, Br or I of the starting FP polymer are only partially replaced with photoactive groups in the MFP polymer.

Thus, the molar proportion of leaving groups (for example of groups Cl when using CTFE or CFE) replaced with photoactive groups may be from 0.5 to 5 mol %; or from 5 to 10 mol %; or from 10 to 20 mol %; or from 20 to 30 mol %; or from 30 to 40 mol %; or from 40 to 50 mol %; or from 50 to 60 mol %; or from 60 to 70 mol %; or from 70 to 80 mol %; or from 80 to 90 mol %; or from 90 to 95 mol %; or more than 95 mol %.

Accordingly, in the polymer PFM, the proportion of residual structural units containing a leaving group (Cl or Br or I) may be, for example, from 0.1 to 0.5 mol %; or from 0.5 to 1 mol %; or from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %. Ranges from 1 to 15 mol %, and preferably from 2 to 10 mol %, are particularly preferred.

Thus also, in the MFP polymer, the proportion of structural units including a photoactive group may be, for example, from 0.1 to 0.5 mol %; or from 0.5 to 1 mol %; or from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %. Ranges from 1 to 15 mol %, and preferably from 2 to 10 mol %, are particularly preferred.

### Preparation of a Film

A fluoropolymer film according to the invention may be prepared by depositing on a substrate: either solely one or more MFP polymers; or at least one FP polymer and at least one MFP polymer. In the latter case, preferably, the monomers containing leaving groups that are used for manufacturing the FP polymer are the same as those used for manufacturing the MFP polymer. Thus, an FP polymer can be combined with an MFP polymer obtained from the FP polymer under consideration.

If only one or more MFP polymers are used, it is preferable for the replacement of the leaving groups with the photoactive groups to be only partial. If at least one FP polymer is used in combination with at least one MFP polymer, only some or all of the leaving groups of the MFP polymer may have been replaced with photoactive groups.

Where at least one FP polymer is combined with at least one MFP polymer, the mass proportion of FP polymer(s) relative to the entirety of the FP and MFP polymers may notably be from 5% to 10%; or from 10% to 20%; or from 20% to 30%; or from 30% to 40%; or from 40% to 50%; or from 50% to 60%; or from 60% to 70%; or from 70% to 80%; or from 80%to 90%; or from 90% to 95%.

The manufacture of the film may comprise a step of depositing MFP (or MFP and FP) polymers onto a substrate, followed by a crosslinking step.

The MFP (or MFP and FP) polymers may also be combined with one or more other polymers, notably fluoropolymers, more particularly such as a P(VDF-TrFE) copolymer.

The substrate may notably be a glass, silicon, polymer-material or metal surface.

To perform the deposition, one preferred method consists in dissolving or suspending the polymer(s) in a liquid vehicle to form an “ink” composition, which is subsequently deposited on the substrate. The liquid vehicle is preferably a solvent. This solvent is preferably chosen from: dimethylformamide; dimethylacetamide; dimethyl sulfoxide; ketones, notably acetone, methyl ethyl ketone, methyl isobutyl ketone and cyclopentanone; furans, notably tetrahydrofuran; esters, notably methyl acetate, ethyl acetate, propyl acetate, butyl acetate and propylene glycol methyl ethyl acetate; carbonates, notably dimethyl carbonate; and phosphates, notably triethyl phosphate. Mixtures of these compounds may also be used.

The total mass concentration of polymers in the liquid vehicle may notably be from 0.1% to 30%, preferably from 0.5% to 20%.

The ink may optionally comprise one or more additives, notably chosen from surface tension modifiers, rheology modifiers, ageing resistance modifiers, adhesion modifiers, pigments or dyes, and fillers (including nanofillers). Preferred additives are notably cosolvents which modify the surface tension of the ink. In particular, in the case of solutions, the compounds may be organic compounds that are miscible with the solvents used. The ink composition may also contain one or more additives which were used for the synthesis of the polymer(s).

Advantageously, the present invention does not use any photoinitiating additive. The reason for this is that, by virtue of the presence of the photoactive groups on the MFP polymer, the addition of a photoinitiating additive is unnecessary.

In certain embodiments, the ink comprises at least one crosslinking adjuvant, preferably a crosslinking agent.

The presence of a crosslinking agent has the advantage of forming covalent bonds with the polymer, the result of which is that the resistance of the polymer to the solvent is improved.

The crosslinking agent may be chosen, for example, from molecules, oligomers and polymers which bear at least two reactive double bonds, such as triallyl isocyanaurate (TAIC), polybutadiene; compounds which bear at least two reactive carbon-carbon or carbon-nitrogen triple bonds, such as tripropargylamine; derivatives thereof, and mixtures thereof.

The crosslinking agent may also and preferentially be a (meth)acrylic monomer which is bifunctional or polyfunctional in terms of reactive double bonds. The crosslinkable composition may contain one or more monomers of this type.

Said (meth)acrylic monomer which is bifunctional or polyfunctional in terms of reactive double bonds may be a bifunctional or polyfunctional (meth)acrylic monomer or oligomer. As regards monomers that are of use in the invention, mention may be made of monomers and oligomers containing at least two reactive double bonds of (meth)acrylic type. It is these reactive double bonds which, by means of a radical polymerization initiator, will allow the polymerization and crosslinking of the (meth)acrylic network within the [electroactive fluorinated copolymer—(meth)acrylic crosslinked network] structure. As a result, any purely (meth)acrylic bifunctional or polyfunctional monomer, for instance dodecane dimethacrylate, is of use in the invention.

Usually, however, the (meth)acrylic monomers or oligomers have chemical structures derived from functions other than pure alkane chemistry, such as diols, triols or polyols, polyesters, ethers, polyethers, polyurethane, epoxies, cyanurates or isocyanurates. Provided that, in their chemical structure, which as a result is mixed (not purely of hydrocarbon-based nature: of alkane type), these monomers include at least two (meth)acrylic functions that are reactive in radical polymerization, they become of use for the invention. Mention may thus be made, for example, of the following compounds: 1,3-butylene glycol di(meth)acrylate, butanediol di(meth)acrylate, 1,6-hexanediol di(meth)acrylate, alkoxylated hexanediol di(meth)acrylate, alkoxylated neopentyl glycol di(meth)acrylate, dodecyl di(meth)acrylate, cyclohexanedimethanol di(meth)acrylate, diethylene glycol di(meth)acrylate, dipropylene glycol di(meth)acrylate, linear alkane di(meth)acrylate, ethoxylated bisphenol A di(meth)acrylate, ethylene glycol di(meth)acrylate, neopentyl glycol di(meth)acrylate, tricyclodecanedimethanol diacrylate, triethylene glycol di(meth)acrylate, tetraethylene glycol di(meth)acrylate, tripropylene glycol di(meth)acrylate, ditrimethylolpropane tetra(meth)acrylate, ethoxylated pentaerythritol tetra(meth)acrylate, dipentaerythritol penta(meth)acrylate, penta(meth)acrylate ester, pentaerythritol tetra(meth)acrylate, ethoxylated trimethylolpropane tri(meth)acrylate, alkoxylated trimethylolpropane tri(meth)acrylate, trimethylolpropane tri(meth)acrylate, pentaerythritol tri(meth)acrylate, propoxylated trimethylolpropane tri(meth)acrylate, trimethylolpropane trimethacrylate, dodecanediol di(meth)acrylate, dodecane di(meth)acrylate, dipentaerythritol penta/hexa(meth)acrylate, pentaerythritol tetra(meth)acrylate, ditrimethylolpropane tetra(meth)acrylate, propoxylated glyceryl tri(meth)acrylate, tris(2-hydroxyethyl) isocyanurate tri(meth)acrylate, polyester (meth)acrylates, polyether (meth)acrylates, polyethylene glycol (meth)acrylates, polypropylene glycol (meth)acrylates, polyurethane (meth)acrylates, epoxy (meth)acrylates, and combinations thereof.

Preferably, the bifunctional or polyfunctional (meth)acrylic monomer or oligomer may be chosen from: trimethylolpropane triacrylate (such as the product sold by the company Sartomer under the reference SR351), ethoxylated trimethylolpropane triacrylate (such as the product sold by the company Sartomer under the reference SR454), polyacrylate modified aliphatic urethane (such as the product sold by the company Sartomer under the reference CN927).

In other (preferred) embodiments, there is no crosslinking adjuvant, such as a photoinitiator or a crosslinking agent, present in the ink deposited onto the substrate.

The deposition may notably be performed by spin-coating, spray coating, bar coating, dip coating, roll-to-roll printing, screen printing, lithographic printing or inkjet printing.

After deposition, the liquid vehicle is evaporated off.

The fluoropolymer layer thus constituted may notably have a thickness of from 10 nm to 1 mm, preferably from 100 nm to 500 μm, more preferably of 150 nm to 250 μm and more preferably of 50 nm to 50 μm.

The crosslinking step may be notably performed by heat treatment and/or by exposure to an electromagnetic radiation, and preferably by UV irradiation. Preferably, only a portion of the polymer film is crosslinked, according to a predetermined pattern, it being possible to use a mask to protect the portions of the film that are not intended to be crosslinked.

Without wishing to be bound by any theory, it is thought that, during the crosslinking step, the photoactive groups tend to undergo decomposition to form radicals. These radicals are capable of reacting with C—F or C—H groups and/or of recombining together, leading to the crosslinking of the polymer(s).

Without wishing to be bound by any theory, it is thought that, according to one variant of the invention, when a crosslinking coagent is present, the photoactive groups tend to undergo decomposition to form radicals. These radicals are capable of reacting with the crosslinking coagent via a radical polymerization mechanism, leading to the crosslinking of the polymer(s).

Heat treatment may be performed by subjecting the film, for example, to a temperature of from 40° C. to 200° C., preferably from 50 to 150° C., preferably of 60 to 140° C., for example in a ventilated oven or on a hotplate. The heat treatment time may notably be from 1 minute to 4 hours, preferably from 2 minutes to 2 hours, and preferably from 5 to 20 minutes.

The term “UV irradiation” denotes irradiation by electromagnetic radiation at a wavelength of from 200 to 650 nm, and preferably from 220 to 500 nm. Wavelengths from 250 to 450 nm are particularly preferred. The radiation may be monochromatic or polychromatic.

The total UV irradiation dose is preferably less than or equal to 40 J/cm², more preferably less than or equal to 20 J/cm², more preferably less than or equal to 10 J/cm², more preferably less than or equal to 5 J/cm² and more preferably less than or equal to 3 J/cm². A low dose is advantageous for avoiding degradation of the surface of the film.

Preferably, the treatment is performed essentially in the absence of oxygen, again with the aim of preventing any degradation of the film. For example, the treatment may be performed under vacuum, or under an inert atmosphere, or with the film protected from the ambient air with a physical barrier which is impervious to oxygen (a glass plate or polymer film, for example).

According to one variant of the invention, a heat pretreatment and/or a heat post-treatment may be performed, before and/or after the UV irradiation.

The heat pretreatment and the heat post-treatment may notably be performed at a temperature of from 20 to 250° C., preferably from 30 to 150° C., preferably from 40 to 110° C., and, for example, at approximately 100° C., for a time of less than 30 minutes, preferably less than 15 minutes and more preferably less than 10 minutes.

These treatments facilitate the improvement of the efficiency of the crosslinking reaction (reducing the loss of thickness of the film, lowering the required UV dose, enhancing the roughness of the film).

When crosslinking has not been performed on the entirety of the film, a developing step may be subsequently performed, so as to remove the portions of the film not crosslinked and to reveal the geometric pattern desired for the film. Development may be performed by placing the film in contact with a solvent, preferably by immersion in a solvent bath. The solvent may preferably be chosen from: dimethylformamide; dimethylacetamide; dimethyl sulfoxide; ketones, notably acetone, methyl ethyl ketone, methyl isobutyl ketone and cyclopentanone; furans, notably tetrahydrofuran; esters, notably methyl acetate, ethyl acetate, propyl acetate, butyl acetate and propylene glycol methyl ethyl acetate; carbonates, notably dimethyl carbonate; and phosphates, notably triethyl phosphate. Mixtures of these compounds may also be used.

Added to this solvent may be a certain amount of non-solvent liquid, miscible with the solvant, preferably from 50% to 80% by mass relative to the total of the solvent and the non-solvent. The non-solvent liquid may in particular be any solvent other than the following solvents: dimethylformamide; dimethylacetamide; dimethyl sulfoxide; ketones; furans; esters; carbonates; phosphates. It may in particular be a protic solvent, i.e. a solvent comprising at least one H atom bonded to an O atom or to an N atom. Use is preferably made of an alcohol (such as ethanol or isopropanol) or demineralized water. Mixtures of non-solvents may also be used. The presence of a non-solvent in combination with the solvent may enable a further improvement in the sharpness of the patterns obtained, relative to the hypothetical case in which the non-solvent is used only during rinsing.

Development may preferably be performed at a temperature of from 10 to 100° C., preferably from 15 to 80° C., and more preferably from 20 to 60° C. The development time is preferably less than 15 minutes, more preferably less than 10 minutes.

After development, the film may be rinsed with a liquid which is a non-solvent for the fluoropolymer, miscible with the solvent or the solvent/non-solvent mixture. It may in particular be a protic solvent, i.e. a solvent comprising at least one H atom bonded to an O atom or to an N atom. Use is preferably made of an alcohol (such as ethanol or isopropanol) or demineralized water. Mixtures of non-solvents may also be used. This rinsing step improves the sharpness of the film patterns and the roughness of their surface.

Rinsing may notably be performed by spraying the non-solvent onto the crosslinked film. Rinsing may also be performed by immersion in a bath of non-solvent. Preferably, the temperature during rinsing may be from 5 to 80° C., more preferably from 10 to 70° C., and particularly at an ambient temperature of 15 to 35° C. The time of the rinsing step is preferably less than 10 minutes, more preferably less than 5 minutes, and particularly less than 1 minute.

After the optional rinsing, the film may be dried in air, and may optionally undergo a post-crosslinking heat treatment, by exposure to a temperature ranging, for example, from 30 to 150° C. and preferably from 50 to 140° C.

The film according to the invention is preferably characterized by a dielectric constant (or relative permittivity) at 1 kHz and at 25° C. of greater than or equal to 10, more preferably greater than or equal to 15, more preferably greater than or equal to 20, and more preferably greater than or equal to 25.

The dielectric constant may be measured using an impedance meter that is capable of measuring the capacitance of the material with knowledge of the geometric dimensions (thickness and opposing surfaces). Said material is placed between two conductive electrodes.

The film according to the invention may be characterized by a coercive field of less than 30 MV/m, preferably less than 20 MV/m and preferably less than 15 MV/m.

The film according to the invention may also be characterized by a saturation polarization of greater than 30 mC/m², and preferably greater than 50 mC/m²; measured at an electric field of 150 MV/m and at 25° C.

The coercive field and saturation polarization measurements may be obtained by measuring the polarization curves of the material. Said film is placed between two conductive electrodes and a sinusoidal electric field is then applied. Measurement of the current passing through said film affords access to the polarization curve.

### Manufacture of an Electronic Device

The film according to the invention may be used as a layer in an electronic device.

Thus, one or more additional layers may be deposited on the substrate equipped with the film of the invention, for example one or more layers of polymers, of semiconducting materials or of metals, in a manner known per se.

The term “electronic device” means either a single electronic component, or a set of electronic components, which are capable of performing one or more functions in an electronic circuit.

According to certain variations, the electronic device is more particularly an optoelectronic device, i.e. a device that is capable of emitting, detecting or controlling an electromagnetic radiation.

Examples of electronic devices or, where appropriate, optoelectronic devices to which the present invention relates are transistors (notably field-effect transistors), chips, batteries, photovoltaic cells, light-emitting diodes (LEDs), organic light-emitting diodes (OLEDs), sensors, actuators, transformers, haptic devices, electromechanical microsystems, electrocaloric devices, and detectors.

According to a preferred variant, the film according to the invention may be used in a field-effect transistor, notably an organic field-effect transistor, as dielectric layer or part of the dielectric layer.

The electronic and optoelectronic devices are used in and integrated into numerous electronic devices, items of equipment or sub-assemblies and in numerous objects and applications, such as televisions, mobile telephones, rigid or flexible screens, thin-film photovoltaic modules, lighting sources, sensors and energy converters etc.

### EXAMPLES

The following examples illustrate the invention without limiting it.

### Example 1

0.6 g of P(VDF-TrFE-CTFE) terpolymer of molar composition 61.7/28.3/10 was placed in a first Schlenk tube, followed by 10 mL of acetone. The mixture was stirred until the polymer was dissolved. 4-Hydroxybenzophenone (0.79 g, 4.0 mmol), potassium carbonate (0.83 g, 6.0 mmol) and 15 mL of acetone were stirred in a second Schlenk tube under an inert atmosphere for 1 hour at 50° C. After cooling the second solution to room temperature, the contents of the (second) Schlenk tube were filtered through a 1 μm PTFE filter and transferred into the first Schlenk tube, and the first Schlenk tube was heated at 50° C. for 3 days. The solution was then cooled and precipitated twice from water acidified with a few drops of hydrochloric acid. The fleecy white solid was then washed twice with ethanol and twice with chloroform. The modified polymer was dried in a vacuum oven at 60° C. overnight.

The final product was characterized by FTIR, SEC and liquid ¹H NMR. The final polymer contains 8.3 mol % of benzophenone groups.

The infrared spectrum of the polymer was measured before (dashed line) and after (continuous line) modification.

The results may be seen in the graph of FIG. 1. After modification of the polymer, the appearance of the characteristic bands of benzophenone between 1500 and 1900 cm⁻¹ is observed.

The liquid ¹H NMR spectrum of the polymer is also measured before (A) and after (B) modification.

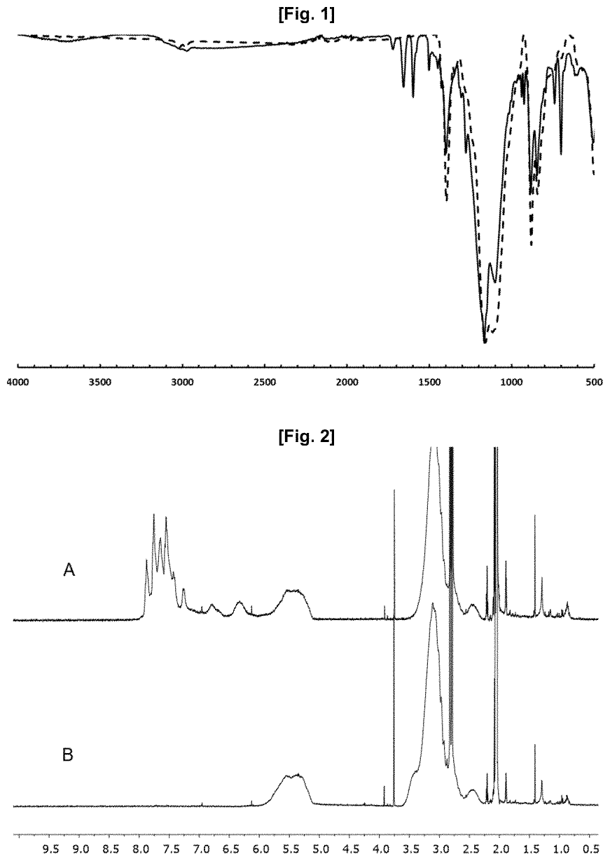

The results may be seen in the graph of FIG. 2. After modification of the polymer, the appearance of the characteristic signals between 7.5 and 9 ppm corresponding to the protons of the aromatic nucleus after modification of the polymer is observed.

### Example 2

A solution with a mass proportion of 4% of polymer as synthesized above was prepared in cyclopentanone. A film of this polymer was formed by spin-coating at 1000 rpm. The polymer underwent a heat pretreatment at 130° C. for 5 minutes. It was then exposed to UV irradiation under an inert atmosphere (nitrogen) with a mask at a dose of 6 J·cm⁻². The polymer selectively irradiated in a pattern underwent a second heat pretreatment at 130° C. for 5 minutes. It was then developed for 2 minutes at room temperature in a mixture of isopropanol and cyclopentanone in an 80/20 mass proportion, and then rinsed with isopropanol.

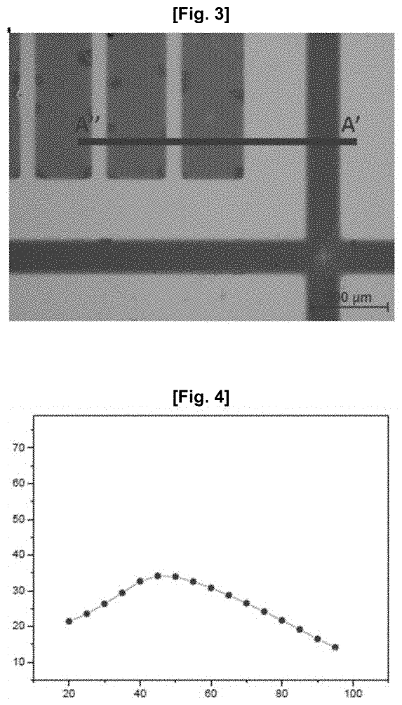

The film obtained is photographed by light microscopy (see FIG. 3). The polymer corresponds to the darker zones.

FIG. 4 is a curve of relative dielectric permittivity at 1 kHz. The crosslinked film conserves good electroactive properties with a relative dielectric permittivity of greater than 20 between 20 and 80° C. and a maximum of greater than 30.

1. Copolymer comprising:
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
fluorinated units of formula (II):
—CX₅X₆—CX₇Z— (II)
in which each of the X₅, X₆ and X₇ is independently chosen from H, F and alkyl groups comprising from 1 to 3 carbon atoms which are optionally partially or totally fluorinated, and in which Z is a photoactive group of formula —Y—Ar—R, Y representing an O atom or an S atom or an NH group, Ar representing an aryl group, and R being a monodentate or bidentate group comprising from 1 to 30 carbon atoms; and
fluorinated units of formula (III):
—CX₅X₆—CX₇Z′— (III)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

2. Copolymer according to claim 1, in which the fluorinated units of formula (I) are derived from monomers chosen from vinylidene fluoride, trifluoroethylene and combinations thereof.

3. Copolymer according to claim 1, in which the fluorinated units of formula (I) comprise both units derived from vinylidene fluoride monomers and units derived from trifluoroethylene monomers, the proportion of units derived from trifluoroethylene monomers being from 15 to 55 mol % relative to the sum of the units derived from vinylidene fluoride and trifluoroethylene monomers.

4. Copolymer according to claim 1, in which the molar proportion of fluorinated units of formula (I) relative to the total amount of units is less than 99%.

5. Copolymer according to claim 1, in which the fluorinated units of formula (III) are derived from monomers chosen from chlorotrifluoroethylene and chlorofluoroethylene, notably 1-chloro-1-fluoroethylene.

6. Copolymer according to claim 5, in which the molar proportion of fluorinated units of formula (II) and of fluorinated units of formula (III) relative to the total amount of units is at least 1%.

7. Copolymer according to claim 5, in which the molar proportion of fluorinated units of formula (II) relative to the sum of the fluorinated units of formula (II) and of formula (III) is from 5% to 90%.

8. Copolymer according to claim 1, in which the group Ar is substituted with the group R in the ortho position relative to Y, and/or in the meta position relative to Y, and/or in the para position relative to Y.

9. Copolymer according to claim 1, in which the group R comprises a carbonyl function.

10. Copolymer according to claim 9, in which the group Ar is a phenyl substituted in the meta position and the group R is an unsubstituted benzoyl group, or the group Ar is a phenyl substituted in the para position and the group R is an unsubstituted benzoyl group, or the group Ar is a phenyl substituted in the para position and the group R is a benzoyl group substituted in the para position with a hydroxyl group, or the group Ar is a phenyl substituted in the meta position and the group R is an acetyl group, or the group Ar is a phenyl substituted in the para position and the group R is an acetyl group, or the group Ar is a phenyl substituted in the ortho position and the group R is a phenylacetyl group substituted α to the carbonyl group with a hydroxyl group, or the group Ar is a phenyl substituted in the meta position and the group R is a phenylacetyl group substituted α to the carbonyl group with a hydroxyl group, or the group Ar is a phenyl substituted in the ortho position and the group R is a phosphine oxide acyl group, or the group Ar is a phenyl substituted in the meta position and the group R is a phosphine oxide acyl group, or the group Ar is a phenyl substituted in the para position and the group R is a phosphine oxide acyl group, or the group Ar is a phenyl substituted in the ortho and meta positions and the group R is a phthaloyl group.

11. Process for preparing a copolymer according to claim 1, comprising:
the provision of a starting copolymer comprising fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
and fluorinated units of formula (III):
—CX₅X₆—CX₇Z′— (III)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I;
and placing of the starting copolymer in contact with a photoactive molecule of formula HY—Ar—R, Y representing an O atom or an S atom, or an NH group, Ar representing an aryl group, and R being a monodentate or bidentate group comprising from 1 to 30 carbon atoms.

12. Process according to claim 11, in which the placing in contact is performed in a solvent chosen from: dimethyl sulfoxide; dimethylformamide; dimethylacetamide; ketones; furans; esters; carbonates; and phosphates.

13. Process according to claim 11, also comprising a step of reacting the photoactive molecule with a base, before placing the starting copolymer in contact with the photoactive molecule.

14. Process according to claim 11, in which the placing of the starting copolymer in contact with the photoactive molecule is performed at a temperature of from 20 to 120° C.

15. Composition comprising the copolymer according to claim 1, wherein the composition is a solution or dispersion of the copolymer in a liquid vehicle.

16. Composition according to claim 15, also comprising a second copolymer comprising:
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
fluorinated units of formula (III):
—CX₅X₆—CX₇Z′— (III)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

17. Composition according to claim 16, in which the fluorinated units of formula (I) of the second copolymer are chosen from units derived from vinylidene fluoride and/or trifluoroethylene.

18. Composition according to claim 16, in which the second copolymer comprises both fluorinated units of formula (I) derived from vinylidene fluoride monomers and fluorinated units of formula (I) derived from trifluoroethylene monomers, the proportion of units derived from trifluoroethylene monomers being from 15 to 55 mol % relative to the sum of the units derived from vinylidene fluoride and trifluoroethylene monomers.

19. Composition according to claim 16, in which the fluorinated units of formula (III) are chosen from units derived from chlorotrifluoroethylene and chlorofluoroethylene, notably 1-chloro-1-fluoroethylene.

20. Composition according to claim 16, comprising from 5% to 95% by weight of the copolymer and from 5% to 95% by weight of the second copolymer; the contents being expressed relative to the sum of the copolymer and of the second copolymer.

21. Composition according to claim 15, also comprising at least one (meth)acrylic monomer which is bifunctional or polyfunctional in terms of reactive double bonds.

22. Composition according to claim 21, in which said (meth)acrylic monomer which is bifunctional or polyfunctional in terms of reactive double bonds is a monomer or an oligomer containing at least two reactive double bonds of (meth)acrylic type or a bifunctional or polyfunctional (meth)acrylic monomer or oligomer chosen from diols, triols or polyols, polyesters, ethers, polyethers, polyurethane, epoxies, cyanurates or isocyanurates.

23. Composition according to claim 22, in which said (meth)acrylic monomer is chosen from the list of the following compounds: dodecane dimethacrylate, 1,3-butylene glycol di(meth)acrylate, butanediol di(meth)acrylate, 1,6-hexanediol di(meth)acrylate, alkoxylated hexanediol di(meth)acrylate, alkoxylated neopentyl glycol di(meth)acrylate, dodecyl di(meth)acrylate, cyclohexanedimethanol di(meth)acrylate, diethylene glycol di(meth)acrylate, dipropylene glycol di(meth)acrylate, linear alkane di(meth)acrylate, ethoxylated bisphenol A di(meth)acrylate, ethylene glycol di(meth)acrylate, neopentyl glycol di(meth)acrylate, tricyclodecanedimethanol diacrylate, triethylene glycol di(meth)acrylate, tetraethylene glycol di(meth)acrylate, tripropylene glycol di(meth)acrylate, ditrimethylolpropane tetra(meth)acrylate, ethoxylated pentaerythritol tetra(meth)acrylate, dipentaerythritol penta(meth)acrylate, penta(meth)acrylate ester, pentaerythritol tetra(meth)acrylate, ethoxylated trimethylolpropane tri(meth)acrylate, alkoxylated trimethylolpropane tri(meth)acrylate, trimethylolpropane tri(meth)acrylate, pentaerythritol tri(meth)acrylate, propoxylated trimethylolpropane tri(meth)acrylate, trimethylolpropane trimethacrylate, dodecanediol di(meth)acrylate, dodecane di(meth)acrylate, dipentaerythritol penta/hexa(meth)acrylate, pentaerythritol tetra(meth)acrylate, ditrimethylolpropane tetra(meth)acrylate, propoxylated glyceryl tri(meth)acrylate, tris(2-hydroxyethyl) isocyanurate tri(meth)acrylate, polyester (meth)acrylates, polyether (meth)acrylates, polyethylene glycol (meth)acrylates, polypropylene glycol (meth)acrylates, polyurethane (meth)acrylates, epoxy (meth)acrylates, and combinations thereof.

24. Process for manufacturing a film, comprising:
depositing a copolymer according to one of claim 1 onto a substrate;
crosslinking the copolymer.

25. Process according to claim 24, in which the crosslinking is performed according to a predefined pattern, the process subsequently comprising the removal of portions of copolymer or composition not crosslinked, by placing in contact with a solvent.

26. Film obtained via the process according to claim 24.

27. Electronic device comprising a film according to claim 26.
